(19) United States
(12) Patent Application Publication
(10) Pub. No.: US 2023/0161240 A1
(43) Pub. Date: May 25, 2023

(54) MANUFACTURING METHOD OF EUV PHOTO MASKS

(71) Applicant: TAIWAN SEMICONDUCTOR MANUFACTURING COMPANY, LTD., Hsinchu (TW)

(72) Inventors: Wei-Che HSIEH, Taipei (TW); Chia-Ching CHU, Hsinchu (TW); Ya-Lun CHEN, Hsinchu City (TW); Yu-Chung SU, Hsinchu City (TW); Tzu-Yi WANG, Hsinchu City (TW); Yahru CHENG, Taipei (TW); Ta-Cheng LIEN, Cyonglin Township (TW); Hsin-Chang LEE, Zhubei City (TW); Ching-Yu CHANG, Yuansun Village (TW)

(21) Appl. No.: 17/736,772

(22) Filed: May 4, 2022

Related U.S. Application Data
(60) Provisional application No. 63/283,162, filed on Nov. 24, 2021.

(51) Int. Cl. G03F 1/24

(52) U.S. Cl. CPC G03F 1/24

(57) ABSTRACT

In a method of manufacturing a reflective mask, an adhesion layer is formed over a mask blank. The mask blank includes a substrate, a reflective multilayer disposed over the substrate, a capping layer disposed over the reflective multilayer, an absorber layer disposed over the capping layer, and a hard mask layer disposed over the absorber layer. A photoresist pattern is formed over the adhesion layer, the adhesion layer is patterned, the hard mask layer is patterned, and the absorber layer is patterned using the patterned hard mask layer as an etching mask. The photoresist layer has a higher adhesiveness to the adhesion layer than to the hard mask layer.

### RELATED APPLICATIONS

This application claims priority to U.S. Provisional Patent Application No. 63/283,162 filed on Nov. 24, 2021, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). The photo mask is an important component in photolithography operations. It is critical to fabricate EUV photo masks having a high contrast with a high reflectivity part and a high absorption part.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A, 1B, 1C, 1D, 1E and 1F show EUV photo mask blanks according to embodiments of the present disclosure.

FIGS. 2A, 2B, 2C, 2D and 2E schematically illustrate a method of fabricating an EUV photo mask according to an embodiment of the present disclosure.

FIGS. 3A, 3B, 3C, 3D and 3E schematically illustrate a method of fabricating an EUV photo mask according to an embodiment of the present disclosure.

FIGS. 4A, 4B, 4C, 4D, 4E and 4F schematically illustrate a method of fabricating an EUV photo mask and FIG. 4G shows a flow chart thereof according to an embodiment of the present disclosure.

FIGS. 5A, 5B, 5C, 5D, 5E and 5F schematically illustrate a method of fabricating an EUV photo mask and FIG. 5G shows a flow chart thereof according to an embodiment of the present disclosure.

FIGS. 6A, 6B, 6C, 6D, 6E and 6F schematically illustrate a method of fabricating an EUV photo mask according to an embodiment of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

Embodiments of the present disclosure provide a method of manufacturing an EUV photo mask. More specifically, the present disclosure provides techniques to prevent or suppress collapse or peeling-off of fine resist patterns over a hard mask layer of an EUV photo mask blank.

EUV lithography (EUVL) employs scanners using light in the extreme ultraviolet (EUV) region, having a wavelength of about 1 nm to about 100 nm, for example, 13.5 nm. The mask is a critical component of an EUVL system. Because the optical materials are not transparent to EUV radiation, EUV photo masks are reflective masks. Circuit patterns are formed in an absorber layer disposed over the reflective structure. The absorber has a low EUV reflectivity, for example, less than about 3-5%.

The present disclosure provides methods of manufacturing an EUV reflective photo mask to improve a lithographic resolution and process robustness.

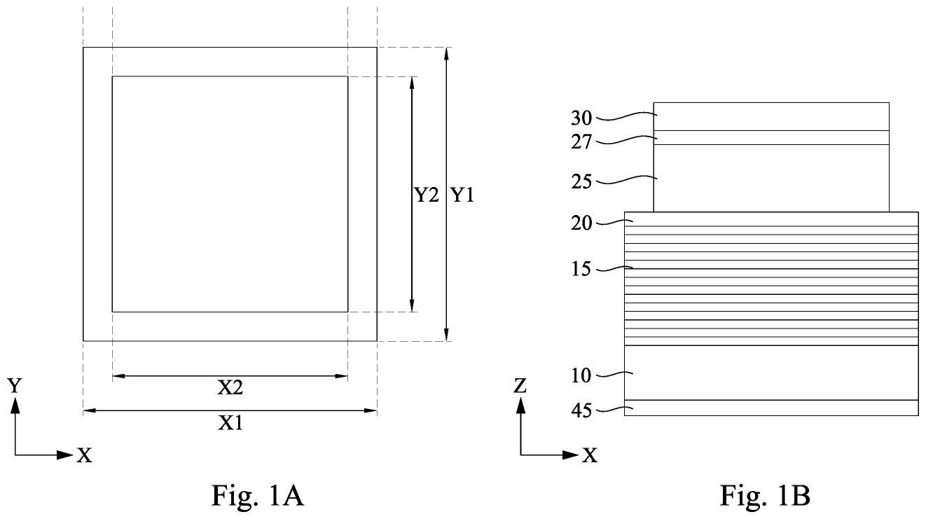

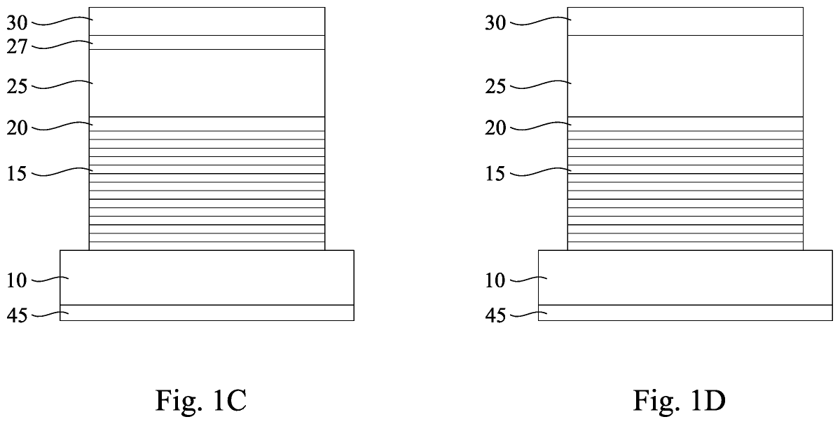

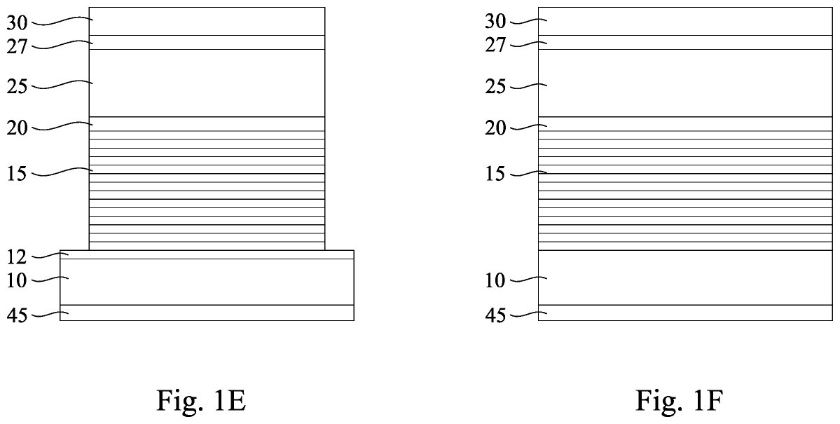

FIGS. 1A and 1B show an EUV reflective photo mask blank according to an embodiment of the present disclosure. FIG. 1A is a plan view (viewed from the top) and FIG. 1B is a cross sectional view along the X direction.

In some embodiments, the EUV photo mask with circuit patterns is formed from an EUV photo mask blank 5. The EUV photo mask blank 5 includes a substrate 10, a multilayer Mo/Si stack 15 of multiple alternating layers of silicon and molybdenum, a capping layer 20, an absorber layer 25, and a hard mask layer 30. Further, a backside conductive layer 45 is formed on the backside of the substrate 10, as shown in FIG. 1B. In some embodiments, an anti-reflective layer 27 is formed on the top surface of the absorber layer 25 as shown in FIG. 1B. In other embodiments, no anti-reflective layer is formed on the top surface of the absorber layer 25 as shown in FIG. 1D.

The substrate 10 is formed of a low thermal expansion material in some embodiments. In some embodiments, the substrate is a low thermal expansion glass or quartz, such as fused silica or fused quartz. In some embodiments, the low thermal expansion glass substrate transmits light at visible wavelengths, a portion of the infrared wavelengths near the visible spectrum (near-infrared), and a portion of the ultraviolet wavelengths. In some embodiments, the low thermal expansion glass substrate absorbs extreme ultraviolet wavelengths and deep ultraviolet wavelengths near the extreme ultraviolet. In some embodiments, the size of the substrate 10 is 152 mm×152 mm (X1×Y1) having a thickness of about 20 mm. In other embodiments, the size of the substrate 10 is smaller than 152 mm×152 mm and equal to or greater than 148 mm×148 mm. The shape of the substrate 10 is square or rectangular.

In some embodiments, the functional layers above the substrate (the multilayer Mo/Si stack 15, the capping layer 20, the absorber layer 25, the anti-reflective layer 27 if used, and the hard mask layer 30) have a smaller width than the substrate 10. In some embodiments, the size of the functional layers X2×Y2 is in a range from about 138 mm×138 mm to 142 mmx 142mm. The shape of the functional layers is square or rectangular as seen in plan view in some embodiments. In other embodiments, X1=X2 and Y1=Y2.

In other embodiments, the absorber layer 25, the anti-reflective layer 27 if used, and the hard mask layer 30 have a smaller size, in the range from about 138 mm×138 mm to 142 mm×142 mm, than the substrate 10, the multilayer Mo/Si stack 15 and the capping layer 20 as shown in FIG. 1C. The smaller size of one or more of the functional layers can be formed by using a frame shaped cover having an opening in a range from about 138 mm×138 mm to 142 mm×142 mm, when forming the respective layers by, for example, sputtering. In other embodiments, all of the layers above the substrate 10 have the same size as the substrate 10.

In some embodiments, the Mo/Si multilayer stack 15 includes from about 30 alternating layers each of silicon and molybdenum to about 60 alternating layers each of silicon and molybdenum. In certain embodiments, from about 40 to about 50 alternating layers each of silicon and molybdenum are formed. In some embodiments, the reflectivity is higher than about 70% for wavelengths of interest (e.g., 13.5 nm). In some embodiments, the silicon and molybdenum layers are formed by chemical vapor deposition (CVD), plasma-enhanced CVD (PECVD), atomic layer deposition (ALD), physical vapor deposition (PVD) (sputtering), or any other suitable film forming method. Each layer of silicon and molybdenum is about 2 nm to about 10 nm thick. In some embodiments, the layers of silicon and molybdenum are about the same thickness. In other embodiments, the layers of silicon and molybdenum are different thicknesses. In some embodiments, the thickness of each silicon layer is about 4 nm and the thickness of each molybdenum layer is about is about 3 nm.

In other embodiments, the multilayer stack 15 includes alternating molybdenum layers and beryllium layers. In some embodiments, the number of layers in the multilayer stack 15 is in a range from about 20 to about 100 although any number of layers is allowed as long as sufficient reflectivity is maintained for imaging the target substrate. In some embodiments, the reflectivity is higher than about 70% for wavelengths of interest e.g., 13.5 nm. In some embodiments, the multilayer stack 15 includes about 30 to about 60 alternating layers of Mo and Be. In other embodiments of the present disclosure, the multilayer stack 15 includes about 40 to about 50 alternating layers each of Mo and Be.

The capping layer 20 is disposed over the Mo/Si multilayer 15 to prevent oxidation of the multilayer stack 15 in some embodiments. In some embodiments, the capping layer 20 is made of ruthenium, a ruthenium alloy (e.g., RuNb, RuZr, RuZrN, RuRh, RuNbN, RuRhN, RuV or RuVN) or a ruthenium based oxide (e.g., RuO₂, RuNbO, RiVO or RuON), having a thickness of from about 2 nm to about 10 nm. In certain embodiments, the thickness of the capping layer 20 is from about 2 nm to about 5 nm. In some embodiments, the capping layer 20 has a thickness of 3.5 nm ±10%. In some embodiments, the capping layer 20 is formed by chemical vapor deposition, plasma-enhanced chemical vapor deposition, atomic layer deposition, physical vapor deposition (e.g., sputtering), or any other suitable film forming method. In other embodiments, a Si layer is used as the capping layer 20.

In some embodiments, one or more additional layer (not shown) are formed between the capping layer 20 and the absorber layer 25. In some embodiments, the additional layer includes a Ta based material, such as TaB, TaO, TaBO or TaBN; silicon; a silicon-based compound (e.g., silicon oxide, SiN, SiON or MoSi); ruthenium; or a ruthenium-based compound (e.g., Ru or RuB). The additional layer has a thickness of about 2 nm to about 20 nm in some embodiments. In some embodiments, the additional layer is formed by chemical vapor deposition, plasma-enhanced chemical vapor deposition, atomic layer deposition, physical vapor deposition, or any other suitable film forming method. In some embodiments, the additional layer functions as an etching stop layer during a patterning operation of the absorber layer.

In other embodiments, the additional layer is a photo catalytic layer that can catalyze hydrocarbon residues formed on the photo mask into CO₂ and/or H₂O with EUV radiation. Thus, an in-situ self-cleaning of the mask surface is performed. In some embodiments, in the EUV scanner system, oxygen and hydrogen gases are injected into the EUV chamber to maintain the chamber pressure (e.g., at about 2 Pa). In addition to the photo catalytic function, the photo catalytic layer is designed to have sufficient durability and resistance to various chemicals and various chemical processes, such as cleaning and etching. For example, the photo catalytic layer may prevent damage to the Ru capping layer 20 from ozonated water used to make the EUV reflective mask in a subsequent process and a resulting significant EUV reflectivity drop. Further, the photo catalytic layer may prevent a Ru oxide formed after Ru oxidation, from being etched away by an etchant, such as Cl₂ or CF₄ gas. In some embodiments, the photo catalytic layer includes one or more of titanium oxide (TiO₂), tin oxide (SnO), zinc oxide (ZnO) and cadmium sulfide (CdS). The thickness of the photo catalytic layer is in a range from about 2 nm to about 10 nm in some embodiments, and is in a range from about 3 nm to about 7 nm in other embodiments. When the thickness is too thin, the photo catalytic layer may not sufficiently function as an etch stop layer. When the thickness is too large, the photo catalytic layer may absorb the EUV radiation.

The absorber layer 25 is disposed over the capping layer 20. In some embodiments, the absorber layer 25 is Ta-based material. In some embodiments, the absorber layer 25 is made of TaN, TaO, TaB, TaBO or TaBN having a thickness from about 25 nm to about 100 nm. In certain embodiments, the absorber layer 25 thickness ranges from about 50 nm to about 75 nm. In other embodiments, the absorber layer 25 includes a Cr based material, such as Cr, CrN, CrON and/or CrCON. In the case of CrON or CrCON, a nitrogen amount is in a range from about 10 atomic % to about 30 atomic % in some embodiments. In some embodiments, the absorber layer 25 has a multilayered structure of Cr, CrN, CrON and/or CrCON. In certain embodiments, a CrN layer is used as the absorber layer 25. When the CrN layer is used, the nitrogen amount is in a range from about 16 atomic % to about 40 atomic % in some embodiments. When the nitrogen amount is in a range from about 16 atomic % to about 30 atomic %, the CrN absorber layer includes Cr and Cr₂N phases. When the nitrogen amount is in a range from about 30 atomic % to about 33 atomic %, the CrN absorber layer substantially consists of a Cr₂N phase (e.g., more than 95 vol %). When the nitrogen amount is in a range from about 33 atomic % to about 40 atomic %, the CrN absorber layer includes Cr2N and CrN phases. The phases can be observed by an electron energy loss spectroscopy (EELS), a transmission electron microscope (TEM), and/or an X-ray diffraction (XRD) analysis. In some embodiments, the two phases form a solid solution. In some embodiments, a nitrogen concentration in the absorber layer 25 is not uniform. In some embodiments, the nitrogen concentration is higher in the middle or the center of the absorber layer 25 than a surface region of the absorber layer 25. In some embodiments, the CrN absorber layer includes one or more impurities other than Cr and N in an amount of less than about 5 atomic %. In some embodiments, the absorber layer 25 further includes one or more elements of Co, Te, Hf and/or Ni.

In some embodiments, an anti-reflective layer 27 is disposed over the absorber layer 25. The anti-reflective layer 27 is made of a silicon oxide in some embodiments, and has a thickness of from about 2 nm to about 10 nm. In other embodiments, a TaB, TaO, TaBO, and/or TaBN layer having a thickness in a range from about 12 nm to about 18 nm is used as the anti-reflective layer. In certain embodiments, the anti-reflective layer 27 is made of tantalum oxide (Ta₂O₅ or non-stoichiometric (e.g., oxygen deficient) tantalum oxide). In some embodiments, the thickness of the anti-reflective layer is from about 3 nm to about 6 nm. In some embodiments, the antireflective layer is formed by chemical vapor deposition, plasma-enhanced chemical vapor deposition, atomic layer deposition, physical vapor deposition, or any other suitable film forming method.

The hard mask layer 30 is disposed over the absorber layer 25 (or the anti-reflective layer 27) in some embodiments. In some embodiments, the hard mask layer 30 is made of a Cr based material, such as CrO, CrON or CrCON, when the absorber layer 25 is made of a Ta-based material. In other embodiments, the hard mask layer 30 is made of a Ta based material, such as TaB, TaO, TaBO or TaBN, when the absorber layer 25 is made of a Cr-based material. In other embodiments, the hard mask layer 30 is made of silicon, a silicon-based compound (e.g., silicon oxide, SiN, SiON or MoSi), ruthenium or a ruthenium-based compound (Ru or RuB). The hard mask layer 30 has a thickness of about 4 nm to about 20 nm in some embodiments. In some embodiments, the hard mask layer 30 includes two or more different material layers. In some embodiments, the hard mask layer 30 is formed by chemical vapor deposition, plasma-enhanced chemical vapor deposition, atomic layer deposition, physical vapor deposition, or any other suitable film forming method.

In some embodiments, one or more of the functional layers above the substrate (the multilayer Mo/Si stack 15, the capping layer 20, the additional layer, the absorber layer 25, the anti-reflective layer 27, and the hard mask layer 30 have a poly-crystalline structure (e.g., nano-crystalline structure) or an amorphous structure.

In some embodiments, a backside conductive layer 45 is disposed on a second main surface of the substrate 10 opposing the first main surface of the substrate 10 on which the Mo/Si multilayer 15 is formed. In some embodiments, the backside conductive layer 45 is made of TaB (tantalum boride) or other Ta based conductive material. In some embodiments, the tantalum boride is crystalline. The crystalline tantalum boride includes TaB, Ta₅B₆, Ta₃B₄ and TaB₂. In other embodiments, the tantalum boride is poly crystalline or amorphous. In other embodiments, the backside conductive layer 45 is made of a Cr based conductive material (CrN or CrON). In some embodiments, the sheet resistance of the backside conductive layer 45 is equal to or smaller than 20 Ω/□. In certain embodiments, the sheet resistance of the backside conductive layer 45 is equal to or more than 0.1 Ω/□. In some embodiments, the surface roughness Ra of the backside conductive layer 45 is equal to or smaller than 0.25 nm. In certain embodiments, the surface roughness Ra of the backside conductive layer 45 is equal to or more than 0.05 nm. Further, in some embodiments, the flatness of the backside conductive layer 45 is equal to or less than 50 nm (within the EUV photo mask). In some embodiments, the flatness of the backside conductive layer 45 is more than 1 nm. A thickness of the backside conductive layer 45 is in a range from about 50 nm to about 400 nm in some embodiments. In other embodiments, the backside conductive layer 45 has a thickness of about 50 nm to about 100 nm. In certain embodiments, the thickness is in a range from about 65 nm to about 75 nm. In some embodiments, the backside conductive layer 45 is formed by atmospheric chemical vapor deposition (CVD), low pressure CVD, plasma-enhanced CVD, laser-enhanced CVD, atomic layer deposition (ALD), molecular beam epitaxy (MBE), physical vapor deposition including thermal deposition, pulsed laser deposition, electron-beam evaporation, ion beam assisted evaporation and sputtering, or any other suitable film forming method. In cases of CVD, source gases include TaCl₅ and BCl₃ in some embodiments.

In some embodiments, as shown in FIG. 1E, a substrate protection layer 12 is formed between the substrate 10 and the multilayer stack 15. In some embodiments, the substrate protection layer 12 is made of Ru or a Ru compound, such as RuO, RuNb, RuNbO, RuZr and RuZrO. In some embodiments, the substrate protection layer 12 is made of the same material as or different material from the capping layer 20. The thickness of the substrate protection layer 12 is in a range from about 2 nm to about 10 nm in some embodiments.

In some embodiments, as shown in FIG. 1F, the functional layers and the substrate have the same size (X1=X2 and Y1=Y2 in FIG. 1A).

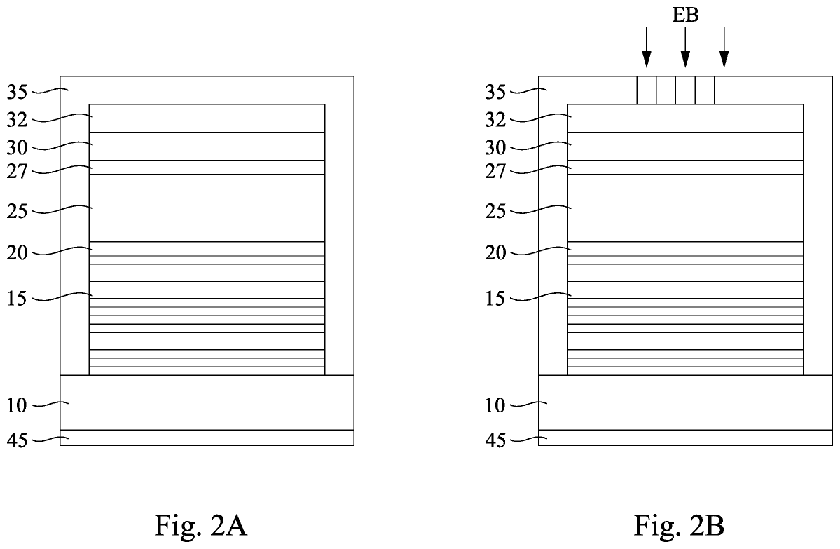

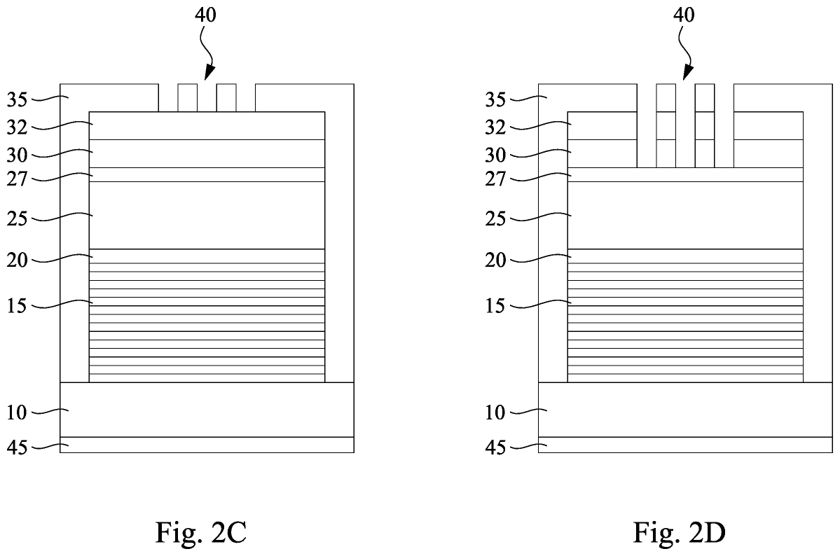

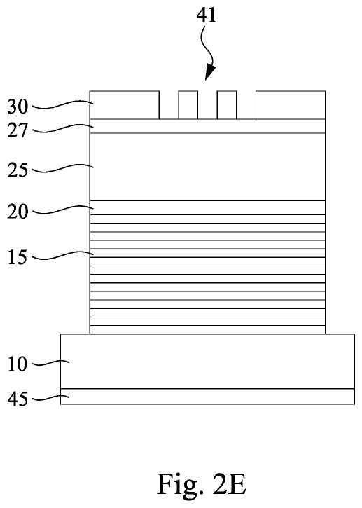

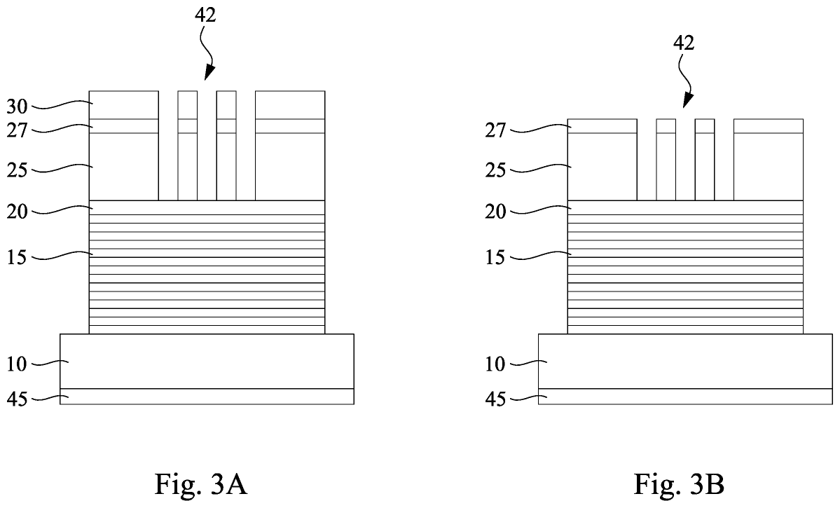

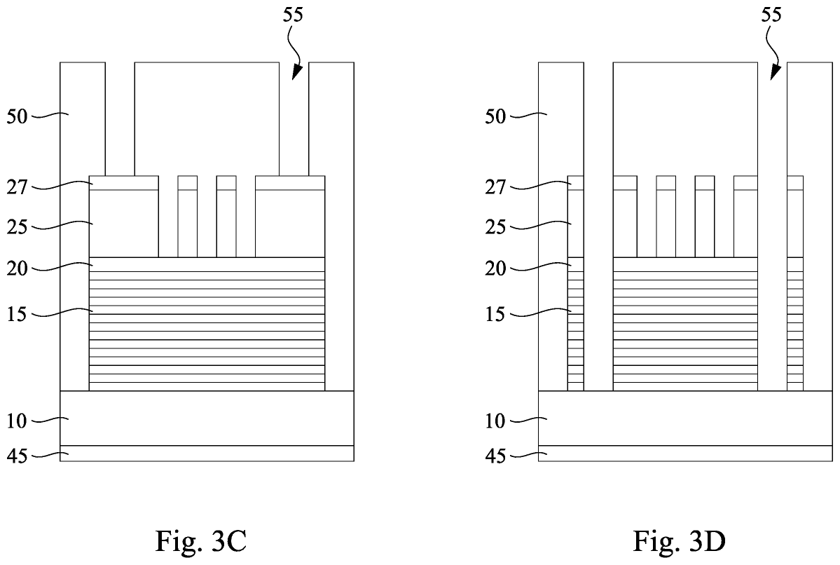

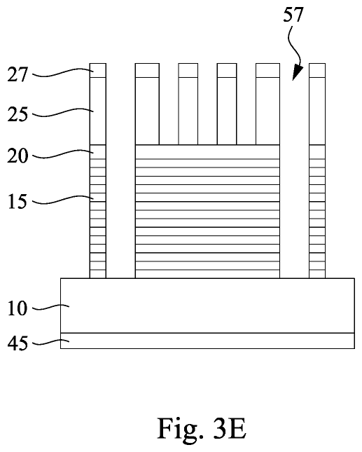

FIGS. 2A-2E and 3A-3E schematically illustrate a method of fabricating an EUV photo mask for use in extreme ultraviolet lithography (EUVL). It is understood that additional operations can be provided before, during, and after the processes shown by FIGS. 2A-3E, and some of the operations described below can be replaced or eliminated for additional embodiments of the method. The order of the operations/processes may be interchangeable.

In the fabrication of an EUV photo mask, an adhesion layer (adhesion enhancement layer) 32 is formed over the hard mask layer 30 of the EUV photo mask blank, and a first photoresist layer 35 is formed over the adhesion layer 32, as shown in FIG. 2A. The photoresist layer 32 is a positive tone or a negative tone photoresist, and has a thickness in a range from about 5 nm to about 120 nm in some embodiments, and is in a range from about 10 nm to about 50 nm in other embodiments. In some embodiments, the photoresist layer is a chemically amplified photoresist or a non-chemically amplified photoresist, sensitive to an electron beam.

The photoresist layer 35 has a higher adhesiveness to the adhesion layer 32 than to the hard mask layer 30. In some embodiments, adhesiveness can be measured by counting or monitoring pattern collapse and/or peeling-off when the photoresist patterns are formed over the respective layers (e.g., the smaller number of pattern collapse and/or peeling-off indicates the higher adhesiveness). In some embodiments, a hexamethyldisilazane (HMDS) treatment distinct from the adhesion layer is performed before applying the photoresist over the adhesion layer 32.

In some embodiments, the adhesion layer 32 includes a carbon-rich layer having a higher carbon concentration than the photoresist layer 35 and/or the hard mask layer 30. With the use of the adhesion layer 32, it is possible to suppress collapse or peeling-off of fine and high-aspect ratio resist patterns after development.

In some embodiments, the adhesion layer 32 is formed by chemical vapor deposition (CVD), plasma-enhanced CVD (PECVD), atomic layer deposition (ALD), physical vapor deposition (PVD) (sputtering), or any other suitable film forming methods. In other embodiments, the adhesion layer 27 is formed by a spin-on coating method of an adhesion layer mixture, followed by soft-baking to remove solvents. In some embodiments, the soft-baking is performed at a temperatures ranging from about 40° C. to 150° C. about for about 30 sec to about 240 sec. In some embodiments, the adhesion layer 32 is optionally cured by an irradiation with light having a wavelength ranging from about 150 nm to 800 nm for about 10 sec to about 120 sec.

In some embodiments, the adhesion layer 32 include an organic polymer. In some embodiments, the adhesion layer mixture for forming the adhesion layer 27 includes a polymeric material, a cross-linker, a crosslinking initiator and a solvent. In some embodiments, the adhesion layer 32 is made of a different material than an organic bottom antireflective coating (BARC) layer, which is used in UV, DUV and/or EUV lithography for a semiconductor wafer/substrate manufacturing process.

In some embodiments, the polymeric material includes a hydrocarbon chain backbone with at least one crosslinking monomer. In some embodiments, the hydrocarbon chain backbone contains at least one of a polyacrylate, a polyimide, a polyurethane, and/or mixtures thereof. In some embodiments, the crosslinking monomer incudes at least one of a hydrocarbon chain that contains a hydroxyl group, an alkoxyl group having a carbon number less than 6, an amine group, a thiol group, an ester group, an alkene group, an alkyne group, an epoxy group, an aziridine group, an oxetane group, an aldehyde group, a ketone group, and/or a carboxylic acid group. In some embodiments, the crosslinking monomers include a homopolymer and/or a copolymer obtained by polymerization of at least one of the following monomers: styrene, hydroxystyrene, hydroxyethyl(meth)acrylate, ethyl(meth)acrylate, (meth)acrylic acid, poly(hydroxystyrene-styrene-methacrylate), poly(4-hydroxy styrene) and/or poly(pyromellitic dianhydride-ethylene glycol-propylene oxide). The weight average molecular weight of the polymeric material ranges from about 100 to about 20,000 Dalton in some embodiments.

In some embodiments, a crosslinker is mixed with the polymeric material and crosslinking initiator to enhance the crosslinking efficiency. The crosslinker includes at least one of an aliphatic polyether, such as polyether polyol, a polyglycidyl ether, a vinyl ether, a glycoluril, a triazine, and/or combinations of these.

In some embodiments, the adhesion layer mixture further contains one or more of a thermal acid generator, a photoacid generator, a photobase generator and/or a free-radical generator, to initiate polymerization.

In some embodiments, a thermal acid generator, which generates an acid when sufficient heat is applied, includes one or more of a butane sulfonic acid, a triflic acid, a nonaflurobutane sulfonic acid, a nitrobenzyl tosylate (e.g., 2-nitrobenzyl tosylate, 2,4-dinitrobenzyl tosylate, 2,6-dinitrobenzyl tosylate, 4-nitrobenzyl tosylate), a benzenesulfonate (e.g., 2-trifluoromethyl-6-nitrobenzyl 4-chlorobenzenesulfonate, 2-trifluoromethyl-6-nitrobenzyl 4-nitro benzenesulfonate), a phenolic sulfonate ester (e.g., phenyl, 4-methoxybenzenesulfonate), an alkyl ammonium salt of organic acids (e.g., triethylammonium salt of 10-camphorsulfonic acid), combinations of these, or the like.

In some embodiments, a photoacid generator, which generates an acid when actinic radiation (UV, DUV, EUV light, or electron beam) is applied, includes one or more of a halogenated triazine, an onium salt, a diazonium salt, an aromatic diazonium salt, a phosphonium salt, a sulfonium salt, an iodonium salt, an imide sulfonate, an oxime sulfonate, a disulfone, an o-nitrobenzylsulfonate, a sulfonated ester, a halogenerated sulfonyloxy dicarboximide, a diazodisulfone, an α-cyanooxyamine-sulfonate, an imidesulfonate, a ketodiazosulfone, a sulfonyldiazoester, a 1,2-di(arylsulfonyl)hydrazines, a nitrobenzyl ester, and/or a s-triazine derivative, any combinations of these, and the like. In some embodiments, examples of photoacid generators include a-(trifluoromethylsulfonyloxy)-bicyclo[2.2.1]hept-5-ene-2,3-dicarbo-ximide (MDT); N-hydroxy-naphthalimide (DDSN); benzoin tosylate; t-butylphenyl-α-(p-toluenesulfonyloxy)-acetate and t-butyl-α-(p-toluenesulfonyloxy)-acetate; triarylsulfonium and diaryliodonium hexafluoroantimonates; hexafluoroarsenates; trifluoromethanesulfonates; iodonium perfluorooctanesulfonate; N-camphorsulfonyloxynaphthalimide; N-pentafluorophenylsulfonyloxynaphthalimide; ionic iodonium sulfonates, such as diaryl iodonium (alkyl or aryl) sulfonate and bis-(di-t-butylphenyl)iodonium camphanylsulfonate; perfluoroalkanesulfonates, such as perfluoropentanesulfonate, perfluorooctanesulfonate, and perfluoromethanesulfonate; aryl (e.g., phenyl or benzyl) triflates, such as triphenylsulfonium triflate or bis-(t-butylphenyl)iodonium triflate; pyrogallol derivatives (e.g., trimesylate of pyrogallol); trifluoromethanesulfonate esters of hydroxyimides; α,α′-bis-sulfonyl-diazomethanes sulfonate esters of nitro-substituted benzyl, alcohols, naphthoquinone-4-diazides, alkyl disulfones, and the like.

In some embodiments, a photobase generator, which generates a base when actinic radiation is applied, includes a quaternary ammonium dithiocarbamate, an aminoketone, an oxime-urethane containing molecule (e.g., dibenzophenoneoxime hexamethylene diurethan), an ammonium tetraorganylborate salt, and/or an N-(2-nitrobenzyloxycarbonyl) cyclic amine, suitable combinations of these, or the like.

In some embodiments, a solvent includes an organic solvent, including any suitable solvent, such as a ketone, an alcohol, a polyalcohol, an ether, a glycol ether, a cyclic ether, an aromatic hydrocarbon, an ester, a propionate, a lactate, a lactic ester, an alkylene glycol monoalkyl ether, an alkyl lactate, an alkyl alkoxypropionate, a cyclic lactone, a monoketone compound that contains a ring, an alkylene carbonate, an alkyl alkoxyacetate, an alkyl pyruvate, an ethylene glycol alkyl ether acetate, a diethylene glycol, a propylene glycol alkyl ether acetate, an alkylene glycol alkyl ether ester, an alkylene glycol monoalkyl ester, or the like.

Specific examples of the solvent include, acetone, methanol, ethanol, toluene, xylene, 4-hydroxy-4-methyl-2-pentanone, tetrahydrofuran, methyl ethyl ketone, cyclohexanone, methyl isoamyl ketone, 2-heptanone, ethylene glycol, ethylene glycol monoacetate, ethylene glycol dimethyl ether, ethylene glycol methylethyl ether, ethylene glycol monoethyl ether, methyl cellosolve acetate, ethyl cellosolve acetate, diethylene glycol, diethylene glycol monoacetate, diethylene glycol monomethyl ether, diethylene glycol diethyl ether, diethylene glycol dimethyl ether, diethylene glycol ethylmethyl ether, diethylene glycol monoethyl ether, diethylene glycol monobutyl ether, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanate, methyl 3-methoxypropionate, ethyl 3-methoxypropionate, methyl 3-ethoxypropionate, ethyl 3-ethoxypropionate, ethyl acetate, butyl acetate, methyl lactate and ethyl lactate, propylene glycol, propylene glycol monoacetate, propylene glycol monoethyl ether acetate, propylene glycol monomethyl ether acetate, propylene glycol monopropyl methyl ether acetate, propylene glycol monobutyl ether acetate, propylene glycol monobutyl ether acetate, propylene glycol monomethyl ether propionate, propylene glycol monoethyl ether propionate, propylene glycol methyl ether acetate, propylene glycol ethyl ether acetate, ethylene glycol monomethyl ether acetate, ethylene glycol monoethyl ether acetate, propylene glycol monomethyl ether, propylene glycol monoethyl ether, propylene glycol monopropyl ether, propylene glycol monobutyl ether, ethylene glycol monomethyl ether, ethylene glycol monoethyl ether, propyl lactate,butyl lactate, ethyl 3-ethoxypropionate, methyl 3-methoxypropionate, methyl 3-ethoxypropionate, and ethyl 3-methoxypropionate, β-propiolactone, β-butyrolactone, γ-butyrolactone, α-methyl-γ-butyrolactone, β-methyl-γ-butyrolactone, γ-valerolactone, γ-caprolactone, γ-octanoic lactone, α-hydroxy-γ-butyrolactone, 2-butanone, 3-methylbutanone, pinacolone, 2-pentanone, 3-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-pentene-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, 3-methylcycloheptanone, propylene carbonate, vinylene carbonate, ethylene carbonate, and butylene carbonate, acetate-2-methoxyethyl, acetate-2-ethoxyethyl, acetate-2-(2-ethoxyethoxy)ethyl, acetate-3-methoxy-3-methylbutyl, acetate methoxy-2-propyl, dipropylene glycol, monomethylether, monoethylether, monopropylether, monobutylether, monophenylether, dipropylene glycol monoacetate, dioxane, ethyl lactate, methyl acetate, ethyl acetate, butyl acetate, methyl pyruvate, ethyl pyruvate, propyl pyruvate, methyl methoxypropionate, ethyl ethoxypropionate, n-methylpyrrolidone (NMP), 2-methoxyethyl ether (diglyme), ethylene glycol monom-ethyl ether, propylene glycol monomethyl ether; methyl proponiate, ethyl proponiate and ethyl ethoxy proponiate, methylethyl ketone, cyclohexanone, 2-heptanone, carbon dioxide, cyclopentanone, cyclohexanone, ethyl 3-ethoxypropionate, propylene glycol methyl ether acetate (PGMEA), methylene cellosolve, butyle acetate, and 2-ethoxyethanol, N-methylformamide, N,N-dimethylformamide, N-methylformanilide, N-methylacetamide, N,N-dimethylacetamide, N-methylpyrrolidone, dimethylsulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, phenyl cellosolve acetate, or the like.

As one of ordinary skill in the art will recognize, the above description for the various compounds (monomers, acid/base generators, solvents, etc.) that may be used for the adhesion layer mixture are intended to be illustrative and are not intended to limit the embodiments in any fashion. Rather, any suitable compound or combination of compounds that perform the desired functions described herein may also be utilized. All such compounds are fully intended to be included within the scope of the embodiments.

In some embodiments, a thickness of the adhesion layer 32 is in a range from about 2 nm to about 50 nm and is in a range from about 5 nm to about 25 nm in other embodiments. When the thickness is smaller than these ranges, sufficient adhesion property may not be obtained, and when the thickness is greater than these ranges, pattern fidelity after the etching of the adhesion layer may be degraded.

In some embodiments, after the adhesion layer mixture is applied over the hard mask layer 30, a polymerization process is performed to polymerize the monomers in the mixture. In some embodiments, the mask blank with the adhesion layer mixture is applied is subjected to a thermal operation, e.g., baking. In some embodiments, the baking operation includes placing the mask blank on a hot plate. In other embodiments, the thermal operation includes an infrared (IR) annealing using an IR lamp, with wavelength in a range from about 800 to 1200 nm. The baking or annealing temperature is in a range from about 90° C. to about 300° C. in some embodiments. In some embodiments, the baking or annealing time is in a range from about 30 sec to about 3000 sec. During the thermal operation, the applied heat generates acids or bases from the crosslinker, which initiate and/or enhances the polymerization in some embodiments.

In some embodiments, the polymerization is performed by applying UV or DUV light. In some embodiments, the UV light has a peak wavelength in a range from about 100 nm to about 800 nm. A low-pressure Hg lamp is used as a UV light source (for about 150 nm to about 400 nm peaks), in some embodiments. In some embodiments, the UV polymerization time is in a range from about 30 sec to about 3000 sec.

After the polymerization of the adhesion layer mixture to form the adhesion layer 32, the first photoresist layer 35 is formed on the adhesion layer 32.

In some embodiments, the adhesion layer 32 includes carbon nano-particles disposed in a polymer. In some embodiments, the diameter of the nano-particles ranges from about 1 nm to about 10 nm. In some embodiments, the adhesion layer 32 include more than 90 atomic % carbon. In some embodiments, the adhesion layer 32 is made of one or more layers (e.g., 2-10 layers) of graphene. In some embodiments, the adhesion layer 32 is made of amorphous carbon having a thickness of about 1 nm to about 10 nm. In some embodiments, one or more graphene layers and/or an amorphous carbon layer are additionally formed over the polymer-based adhesion layer as set forth above.

In some embodiments, the surface portion of the hard mask layer 30 is converted to a carbon-rich layer as the adhesion layer 32. In some embodiments, carbon is implanted into the surface portion of the hard mask layer 30 in a depth ranging from about 5 nm to about 20 nm. In some embodiments, the adhesion layer 32 includes Ta, Cr, Ru, and/or Si (e.g., materials of the hard mask layer) and carbon having a higher carbon concentration than the remaining portion of the hard mask layer 30. In some embodiments, carbon is introduced by using plasma generated from a carbon containing gas. In some embodiments, carbon diffuses into the surface portion of the hard mask layer 30 to a depth ranging from about 2 nm to about 10 nm.

After the adhesion layer 32 and the first photoresist layer 35 are formed, the first photoresist layer 35 is selectively exposed to actinic radiation EB as shown in FIG. 2B. Before the first photoresist layer 35 is formed, the EUV photo mask blank is inspected in some embodiments. The selectively exposed first photoresist layer 35 is developed to form a pattern 40 in the first photoresist layer 35 as shown in FIG. 2C. In some embodiments, the actinic radiation EB is an electron beam or an ion beam. In some embodiments, the pattern 40 corresponds to a circuit pattern of semiconductor device features for which the EUV photo mask will be used to form in subsequent operations. In some embodiments, the thickness of the first photoresist layer 35 on the adhesion layer 32 is in a range from about 100 nm to about 500 nm. In some embodiments, as shown in FIG. 2C, no pattern is extended to the adhesion layer 32. In some embodiments, when the adhesion layer 32 includes a polymeric material, the adhesion layer 32 has been partially or fully polymerized before the e-beam application. In other embodiments, the adhesion layer 32 has not been fully polymerized and the application of the e-beam causes full polymerization of the adhesion layer.

Next, the pattern 40 in the first photoresist layer 35 is extended into the adhesion layer 32 and the hard mask layer 30, thereby forming a pattern 41 in the hard mask layer 30 exposing portions of the absorber layer 25 (or the anti-reflective layer 27), as shown in FIG. 2D. In some embodiments, the etching process includes at least two etching steps, including a first etching to etch the adhesion layer 32 and a second etching to etch the hard mask layer 30 using different etching gases. In other embodiments, one etching process using the same etching gas etches both the adhesion layer 32 and the hard mask layer 30.

In some embodiments, the etching process is a plasma dry etching operation using a chlorine containing gas (e.g., Cl₂, HCl, BCl and CCl₄) and an oxygen containing gas (e.g., O₂) to pattern the hard mask layer 30. In some embodiments, a plasma dry etching operation uses a fluorine containing gas (e.g., a fluorocarbon (CF₄, CHF₃, etc.) and SF₆) to pattern the hard mask layer 30.

In some embodiments, during the etching process of the hard mask layer 30, an etching rate R1 of the photoresist layer 35 is equal to or smaller than an etching rate R2 of the adhesion layer 32, so that the adhesion layer 32 functions as a sacrificial layer. In some embodiments, about 1≤R2/R1≤about 10 is satisfied. In other embodiments, about 2≤R2/R1≤about 8 is satisfied. In other embodiments, R1 is smaller than R2 to enhance pattern transfer fidelity, and about 1≤R1/R2≤about 10 is satisfied. In other embodiments, about 2≤R1/R2≤about 8 is satisfied. The etching selectivity can be controlled by adjusting one or more conditions/parameters of the etching, such as etching gas chemistry, input power, or substrate temperature.

After the pattern 41 in the hard mask layer 30 is formed, the first photoresist layer 35 and the adhesion layer 32 are removed. In some embodiments, the adhesion layer 32 is removed together with the photoresist layer 35 by using a photoresist stripper, such as a mixture of di-ionized water, ammonia, and hydrogen peroxide; a mixture of di-ionized water, hydrochloric acid, and hydrogen peroxide; a mixture of di-ionized water, sulfuric peroxide, and hydrogen peroxide, organic solvents (e.g., PGEE or PGMEA). In some embodiments, a plasma ashing operation using an oxygen containing gas (O₂, O₃, CO, CO₂ and/or H₂O) or a gas containing N₂, H₂, NH₃ and/or N₂H₄ (reducing plasma chemistry) is used. In some embodiments, when the adhesion layer 32 is the surface carbon-rich portion of the hard mask 30, the adhesion layer 32 is not removed at this stage.

Then, the pattern 41 in the hard mask layer 30 is extended into the absorber layer 25 (and the anti-reflective layer 27) forming a pattern 42 in the absorber layer 25 (and the anti-reflective layer 27) exposing portions of the capping layer 25, as shown in FIG. 3A. The anti-reflective layer 27 and the absorber layer 25 are etched by using a suitable wet or dry etchant that is selective to the hard mask layer 30. In some embodiments, a plasma dry etching operation using a chlorine containing gas (e.g., Cl₂, HCl, BCl, and CCl₄) and a oxygen containing gas (e.g., O₂) is used to pattern the absorber layer 25.

Then, the hard mask layer 30 is removed by using wet etching and/or dry etching, as shown in FIG. 3B. In some embodiments, a plasma dry etching operation using a fluorine containing gas (e.g., a fluorocarbon (CF₄, CHF₃, etc.) and SF₆) is used to remove the hard mask layer 30.

Further, as shown in FIG. 3C, a second photoresist layer 50 is formed over the absorber layer 25 filling the pattern 42 in the absorber layer 25. In some embodiments, no adhesion layer is applied before forming the second photoresist layer 50. The second photoresist layer 50 is selectively exposed to actinic radiation such as an electron beam, ion beam or UV radiation. The selectively exposed second photoresist layer 50 is developed to form a pattern 55 in the second photoresist layer 50 as shown in FIG. 3C. The pattern 55 corresponds to a black border surrounding the circuit patterns. A black border is a frame shape area created by removing all the multilayers on the EUV photo mask in the region around a circuit pattern area. It is created to prevent exposure of adjacent fields when printing an EUV photo mask on a wafer. The width of the black border is in a range from about 1 mm to about 5 mm in some embodiments.

Next, the pattern 55 in the second photoresist layer 50 is extended into the anti-reflective layer 27 if used, the absorber layer 25, the capping layer 20, and the Mo/Si multilayer 15 forming a pattern 57 in the anti-reflective layer 27, the absorber layer 25, the capping layer 20, and the Mo/Si multilayer 15 exposing portions of the substrate 10, as shown in FIG. 3D. The pattern 57 is formed by etching, in some embodiments, using one or more suitable wet or dry etchants that are selective to each of the layers that are etched. In some embodiments, plasma dry etching is used.

Then, the second photoresist layer 50 is removed by a suitable photoresist stripper to expose the upper surface of the oxide layer 27 as shown in FIG. 3E. The black border pattern 57 in the anti-reflective layer 27, the absorber layer 25, the capping layer 20, and the Mo/Si multilayer 15 defines a black border of the photo mask in some embodiments of the disclosure. Further, the photo mask undergoes a cleaning operation, inspection, and the photo mask is repaired as necessary, to provide a finished photo mask.

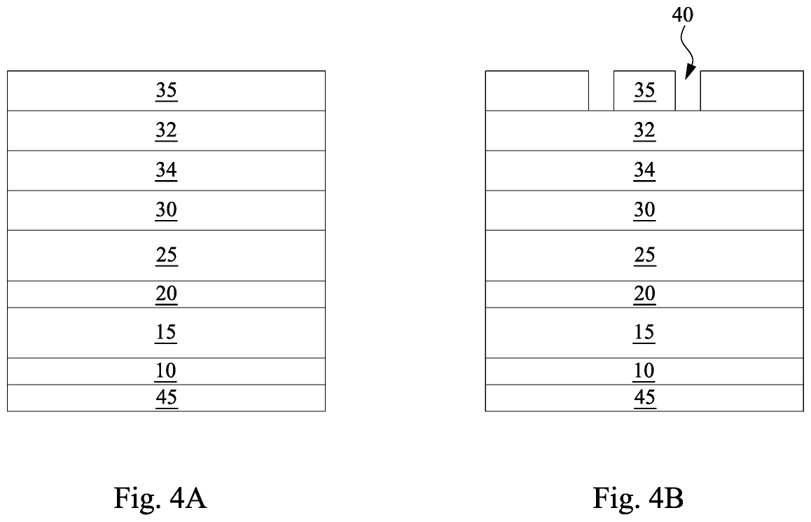

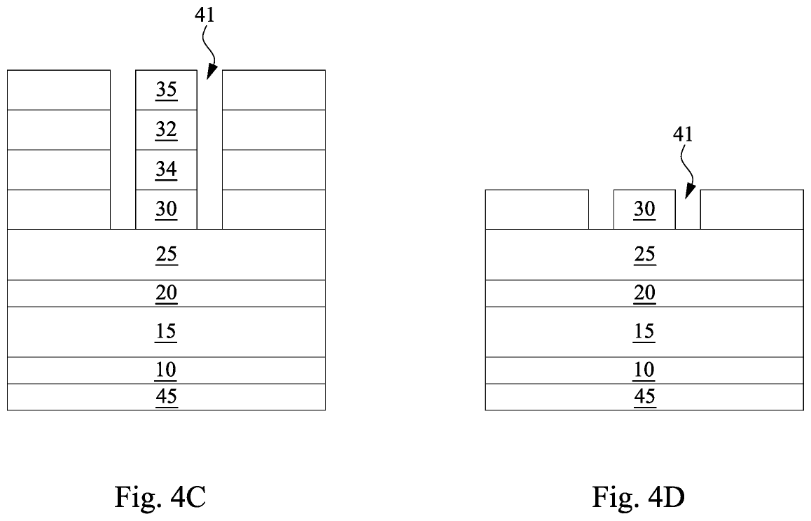

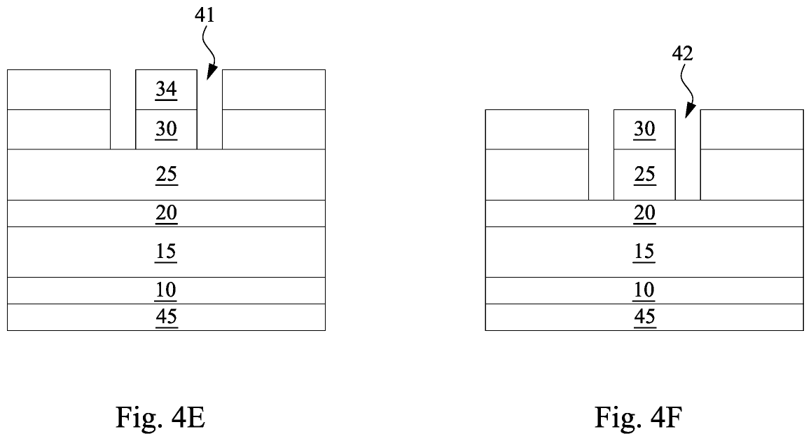

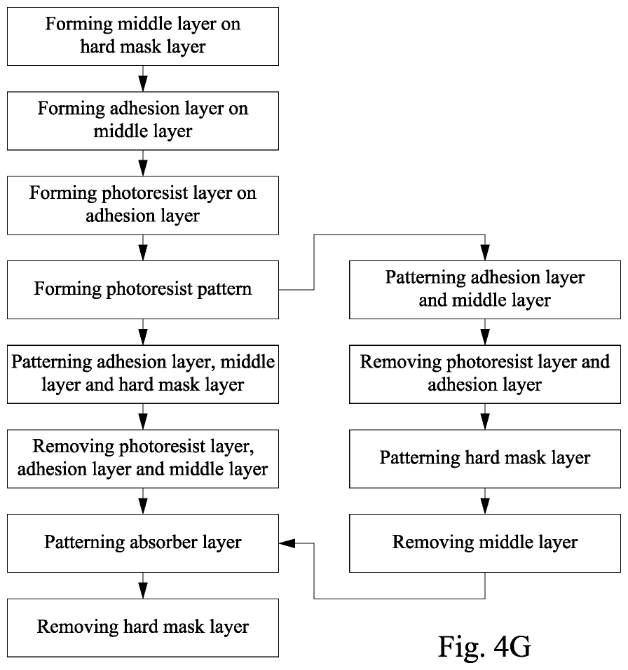

FIGS. 4A-4F schematically illustrate a sequential method of fabricating an EUV photo mask for use in extreme ultraviolet lithography (EUVL) and FIG. 4G is a flow chart thereof according to embodiments of the present disclosure. It is understood that additional operations can be provided before, during, and after the processes shown by FIGS. 4A-4G, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, a middle layer 34 is formed between the adhesion layer 32 and the hard mask layer 30 as shown in FIG. 4A. In some embodiments, the middle layer 34 is a silicon-containing layer. In some embodiments, the middle layer 34 is one or more layers of silicon oxide, silicon nitride, SiON, SiBN, SiBC, SiBCN, SiC, SiOC, SiOCN or any suitable inorganic silicon compound. In some embodiments, the middle layer is amorphous or polycrystalline Si, SiGe or SiC. In some embodiments, the adhesion layer 32 includes a carbon-rich layer having a higher carbon concentration than the middle layer 34.

In some embodiments, the middle layer 34 includes a silicon containing polymer, such as polysiloxane. A silicon amount of polysiloxane is about 40 wt % to about 70 wt % in some embodiments. In contrast, the middle layer of the present disclosure includes silicon in an amount of 50 wt % or more.

Accordingly, a higher etching selectivity and a lower CD variation between the middle layer 34 and bottom layer 30 are obtained. In some embodiments, the middle layer 34 is free from a silicon polymer, such as polysiloxane. In other embodiments, the middle layer 34 contains a silicon polymer, such as polysiloxane, and silicon particles or clusters such that the silicon amount in the middle layer 34 is about 40 wt % to about 70 wt %. In some embodiments, a diameter of the silicon particles is in a range from 1 nm to 20 nm, and is in a range from about 2 nm to about 10 nm in other embodiments. In some embodiments, the middle layer 34 includes a metal or metal alloy that can absorb EUV light. In some embodiments, the middle layer includes a transition metal, such as Ta, Pd, Jr, Ni, Ti, Sn, Au or alloys thereof. In some embodiments, the middle layer includes one or more materials used for the absorber layer 25 as set forth above. In other embodiments, the middle layer 34 includes a different material from the absorber layer 25. In some embodiments, the metal or metal alloy is contained in the middle layer as particles having a diameter in a range from 1 nm to 20 nm, or from about 2 nm to about 10 nm. In some embodiments, the middle layer 34 is an organic polymer containing silicon particles and/or metal particles as set forth above.

In some embodiments, a minimum thickness of the middle layer is about 2 nm, about 5 nm or about 10 nm, and a maximum thickness of the middle layer is about 30 nm, about 50 nm, about 100 nm, about 150 nm or about 200 nm. The middle layer 34 is formed by CVD, PVD, ALD or any other suitable film formation process. In some embodiments, a minimum thickness of the adhesion layer is about 2 nm, about 5 nm or about 10 nm, and a maximum thickness of the adhesion layer is about 15 nm, about 25 nm or about 50 nm.

After the photoresist layer 35 is formed, similar to FIGS. 2B and 2C, a resist pattern 40 is formed as shown in FIG. 4B.

Then, the adhesion layer 32 and the middle layer 34 are etched by using the photoresist layer 35 as an etching mask, as shown in FIG. 4C. The middle layer 34 has a high etching selectivity to the photoresist layer 35 and the hard mask layer 30. In some embodiments, a silicon-containing middle layer 34 can be etched by mixing gas plasma CF₄ and O₂ with an etching rate up to about 50 nm/s to about 70 nm/s, whereas the hard mask layer 30 made of, for example, CrON, may be etched with an etching rate up to about 3 nm/s to about 5 nm/s, and the etching rate of the photoresist layer is about 22 nm/s to about 24 nm/s. In some embodiments, the etch selectivity of the middle layer 34 to hard mask layer 30 is in a range from about 60 to about 100, which can help facilitate thinning of the middle layer.

In some embodiments, the hard mask layer 30 is sequentially and/or continuously etched by using the photoresist layer 35, the adhesion layer 32 and the middle layer 34 as an etching mask, to form the pattern 41 in the hard mask layer 30, as shown in FIG. 4C. After the pattern 41 is formed as shown in FIG. 4C, the photoresist layer 35, and the adhesion layer 32 are removed as explained with respect to FIG. 2E, as shown in FIG. 4D. In some embodiments, plasma dry etching or wet etching is used to remove the middle layer 34. In some embodiments, when the middle layer 34 is made of a silicon-oxide based material, a HF-based solution can be used to remove the middle layer. In some embodiments, when the middle layer 34 is made of a silicon-nitride based material, a H₃PO₄-based solution can be used to remove the middle layer. In some embodiments, a mixing gas plasma of fluorocarbon (e.g., CF₄) and O₂ is used to remove the silicon-containing middle layer. When the middle layer 34 is an organic polymer based material, the middle layer 34 can be removed together with the photoresist layer 35 and the adhesion layer 32 in some embodiments.

In some embodiments, the etching stops on the hard mask layer 30 and then the photoresist layer 35 and the adhesion layer 32 are removed. Then, the hard mask layer 30 is patterned by using the patterned middle layer 34 as an etching mask, as shown in FIG. 4E. Then, the middle layer 34 is removed.

Subsequently, as shown in FIG. 4F, the absorber layer 25 (and the anti-reflective layer 27) is etched using the patterned hard mask layer 30 as an etching mask. Then, the operations explained with respect to FIGS. 3B-3E are performed.

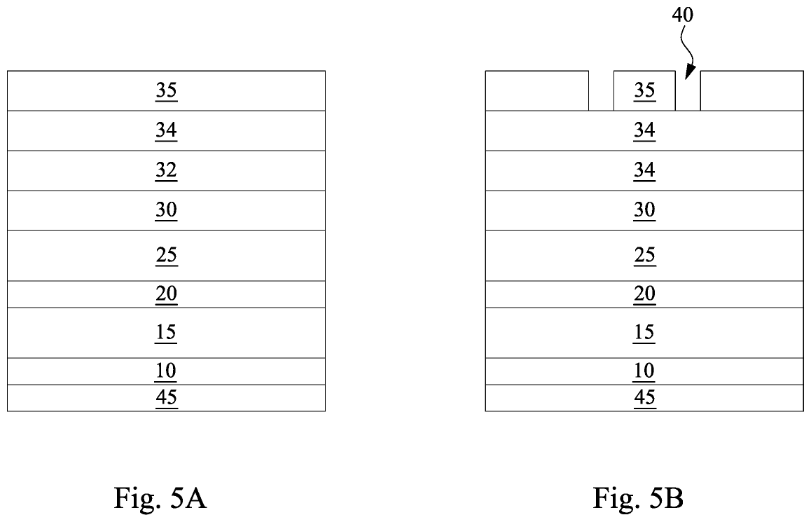

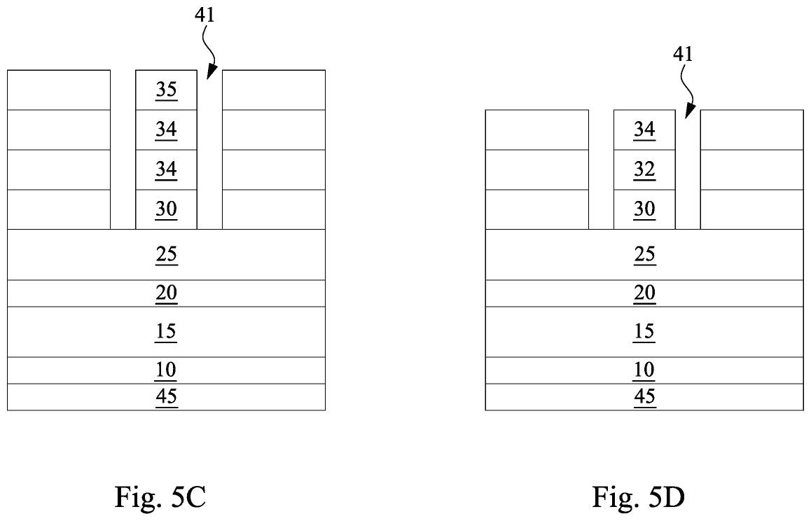

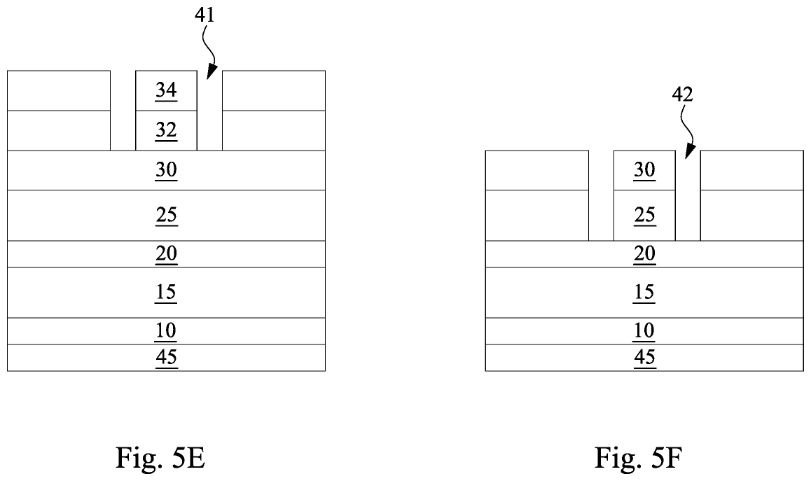

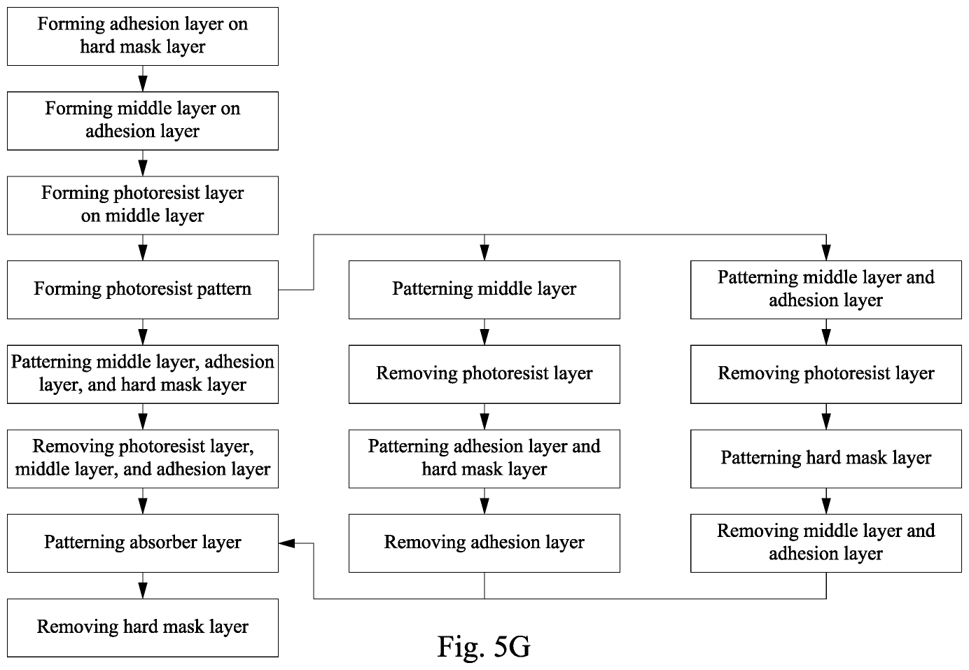

FIGS. 5A-5F schematically illustrate a sequential method of fabricating an EUV photo mask for use in extreme ultraviolet lithography (EUVL) and FIG. 5G is a flow chart thereof according to embodiments of the present disclosure. It is understood that additional operations can be provided before, during, and after the processes shown by FIGS. 5A-5G, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, the middle layer 34 is formed between the adhesion layer 32 formed on the hard mask layer 30 and the photoresist layer 35, as shown in FIG. 5A. The adhesin layer 32 improves adhesiveness between the middle layer 34 and the hard mask layer 30, and improves line width/edge roughness of the patterned hard mask layer 30. In some embodiments, a hexamethyldisilazane (HMDS) treatment distinct from the middle layer is performed before applying the photoresist over the middle layer 34.

In some embodiments, a minimum thickness of the middle layer 34 is about 2 nm, about 5 nm or about 10 nm, and a maximum thickness of the middle layer is about 30 nm, about 50 nm, about 100 nm, about 150 nm or about 200 nm. In some embodiments, a minimum thickness of the adhesion layer is about 2 nm, about 5 nm or about 10 nm, and a maximum thickness of the adhesion layer is about 50 nm, about 100 nm, about 200 nm, about 400 nm or about 800 nm.

After the photoresist layer 35 is formed, similar to FIGS. 2B, 2C and 4B, a resist pattern 40 is formed as shown in FIG. 5B. Then, in some embodiments, the middle layer 34, the adhesion layer 32 and the hard mask layer 30 are etched (patterned) by using the photoresist layer 35 as an etching mask, as shown in FIG. 5C. Then, the photoresist layer 35, the middle layer 34 and the adhesion layer 32 are removed, and the absorber layer 25 is patterned by using the patterned hard mask layer 30 as an etching mask as shown in FIG. 5F.

In other embodiments, after the middle layer 34 is patterned, the photoresist layer 35 is removed, and then the adhesion layer 32 and the hard mask layer 30 are patterned by using the middle layer 34 as an etching mask, as shown in FIG. 5D. Then, the middle layer 34 and the adhesion layer 32 are removed, and the absorber layer 25 is patterned by using the patterned hard mask layer 30 as an etching mask as shown in FIG. 5F.

In other embodiments, after the middle layer 34 and the adhesion layer 32 are patterned, the photoresist layer 35 is removed as shown in FIG. 5E, and then the hard mask layer 30 is patterned by using the middle layer 34 as an etching mask, as shown in FIG. 5D. Then, the middle layer 34 and the adhesion layer 32 are removed, and the absorber layer 25 is patterned by using the patterned hard mask layer 30 as an etching mask as shown in FIG. 5F

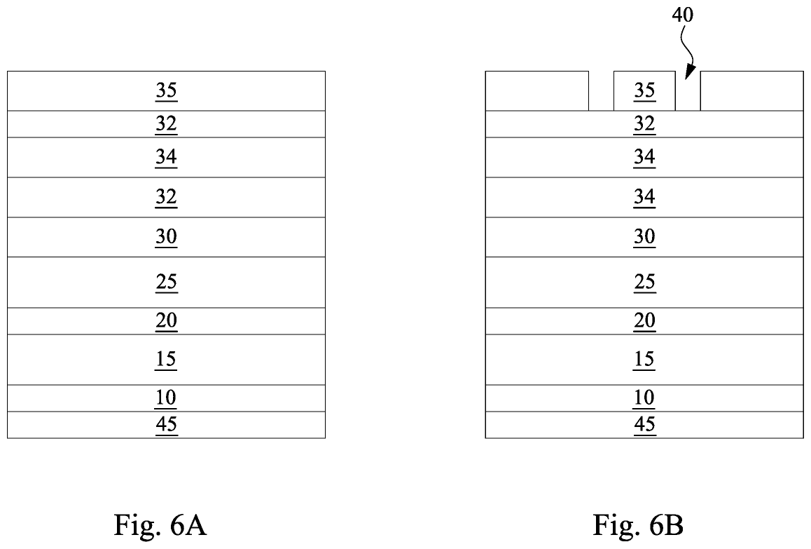

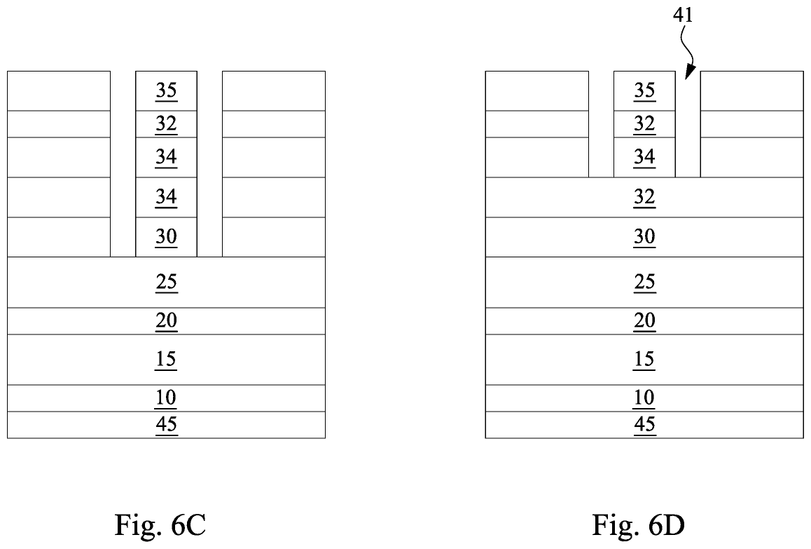

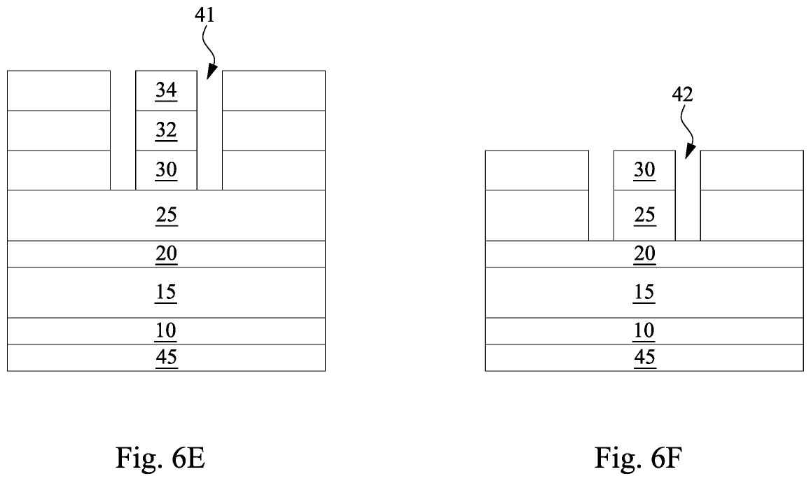

FIGS. 6A-6F schematically illustrate a sequential method of fabricating an EUV photo mask for use in extreme ultraviolet lithography (EUVL). It is understood that additional operations can be provided before, during, and after the processes shown by FIGS. 6A-6F, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, two adhesion layers 32 are provided. One adhesion layer 32 is below the middle layer 34 (similar to FIG. 5A) and the other is above the middle layer 34 (similar to FIG. 4A), as shown in FIG. 6A. In some embodiments, the thickness of the adhesion layer 32 below the middle layer 34 is smaller than the thickness of the adhesion layer 32 above the middle layer 34. In some embodiments, the material of the adhesion layer 32 below the middle layer 34 is the same as the material of the adhesion layer 32 above the middle layer 34. In other embodiments, the material of the adhesion layer 32 below the middle layer 34 is different from the material of the adhesion layer 32 above the middle layer 34.

After the photoresist layer 35 is formed, a resist pattern 40 is formed as shown in FIG. 6B. Then, in some embodiments, the upper adhesion layer 32, the middle layer 34, the lower adhesion layer 32 and the hard mask layer 30 are etched (patterned) by using the photoresist layer 35 as an etching mask, as shown in FIG. 6C. Then, the photoresist layer 35, the upper adhesion layer 32, the middle layer 34 and the lower adhesion layer 32 are removed, and the absorber layer 25 is patterned by using the patterned hard mask layer 30 as an etching mask as shown in FIG. 6F.

In other embodiments, the upper adhesion layer 32 and the middle layer 34 are patterned by using the photoresist layer 35 as an etching mask, as shown in FIG. 6D, the photoresist layer 35 and the upper adhesion layer 32 are removed. Then, the lower adhesion layer 32 and the hard mask layer 30 are patterned by using the middle layer 34 as an etching mask, as shown in FIG. 6E. Then, the middle layer 34 and the lower adhesion layer 32 are removed, and the absorber layer 25 is patterned by using the patterned hard mask layer 30 as an etching mask as shown in FIG. 6F.

In the present embodiments, an adhesion layer is used below the photoresist layer to improve adhesiveness between the hard mask layer and the photoresist patterns, thereby suppressing collapse and/or peeling-off of the fine photoresist patterns.

It will be understood that not all advantages have been necessarily discussed herein, no particular advantage is required for all embodiments or examples, and other embodiments or examples may offer different advantages.

According to one aspect of the present application, in a method of manufacturing a reflective mask, an adhesion layer is formed over a mask blank. The mask blank includes a substrate, a reflective multilayer disposed over the substrate, a capping layer disposed over the reflective multilayer, an absorber layer disposed over the capping layer, and a hard mask layer disposed over the absorber layer. A photoresist pattern is formed over the adhesion layer, the adhesion layer is patterned, the hard mask layer is patterned, and the absorber layer is patterned using the patterned hard mask layer as an etching mask. The photoresist layer has a higher adhesiveness to the adhesion layer than to the hard mask layer. In one or more of the foregoing and following embodiments, the adhesion layer includes a carbon-rich layer having a higher carbon concentration than at least one of the photoresist layer or the hard mask layer. In one or more of the foregoing and following embodiments, a thickness of the adhesion layer is in a range from 2 nm to 50 nm. In one or more of the foregoing and following embodiments, the adhesion layer includes an organic polymer. In one or more of the foregoing and following embodiments, the adhesion layer includes carbon more than 90 atomic %. In one or more of the foregoing and following embodiments, the adhesion layer includes one or more layers of graphene. In one or more of the foregoing and following embodiments, the adhesion layer includes an amorphous carbon.

In accordance with another aspect of the present disclosure, in a method of manufacturing a reflective mask, an adhesion layer over a mask blank. The mask blank including a substrate, a reflective multilayer disposed over the substrate, a capping layer disposed over the reflective multilayer, an absorber layer disposed over the capping layer, and a hard mask layer disposed over the absorber layer. A photoresist pattern over the adhesion layer, the adhesion layer is patterned, the hard mask layer is patterned, and the absorber layer is patterned using the patterned hard mask layer as an etching mask. The adhesion layer is formed by coating a adhesion layer mixture over the hard mask layer, and applying a heat to the coated adhesion layer mixture. In one or more of the foregoing and following embodiments, the adhesion layer mixture includes a polymeric material, a cross-linker, an crosslinking initiator and solvents. In one or more of the foregoing and following embodiments, the polymeric material includes a hydrocarbon chain backbone with at least one crosslinking monomer. In one or more of the foregoing and following embodiments, the hydrocarbon chain backbone includes one or more of a polyacrylate, a polyimide or a polyurethane. In one or more of the foregoing and following embodiments, the crosslinking monomer includes at least one selected from the group consisting of a hydrocarbon chain that contains a hydroxyl group, an alkoxyl group having a carbon number less than 6, an amine group, a thiol group, a ester group, an alkene group, an alkyne group, an epoxy group, an aziridine group, an oxetane group, an aldehyde group, a ketone group, and a carboxylic acid group. In one or more of the foregoing and following embodiments, the crosslinking monomer includes at least one of a homopolymer or a copolymers obtained by polymerization of at least one monomer selected from the group consisting of styrene, hydroxystyrene, hydroxyetheyl(meth)acrylate, ethyl(meth)acrylate, (meth)acrylic acid, poly(hydroxystyrene-styrene-methacrylate), poly(4-hydroxystyerene) and poly(pyromellitic dianhydride-ethylene glycol-propylene oxide). In one or more of the foregoing and following embodiments, a molecular weight of the polymeric material ranges from 100 Dalton to 20,000 Dalton. In one or more of the foregoing and following embodiments, the cross-linker includes at least one selected from the gourp consisting of a polyether polyol, a polyglycidyl ether, a vinyl ether, a glycouril, and a triazene. In one or more of the foregoing and following embodiments, the coated adhesion layer mixture is subjected to polymerization by applying heat or ultra violet (UV) light.

In accordance with another aspect of the present disclosure, in a method of manufacturing a reflective mask, a middle layer is formed over a mask blank. The mask blank including a substrate, a reflective multilayer disposed over the substrate, a capping layer disposed over the reflective multilayer, an absorber layer disposed over the capping layer, and a hard mask layer disposed over the absorber layer. A first adhesion layer is formed over the middle layer, a photoresist pattern is formed over the adhesion layer, the adhesion layer is patterned, the hard mask layer is patterned, and the absorber layer is patterned using the patterned hard mask layer as an etching mask. In one or more of the foregoing and following embodiments, the first adhesion layer includes a carbon-rich layer having a higher carbon concentration than at least one of the photoresist layer, the middle layer or the hard mask layer. In one or more of the foregoing and following embodiments, the middle layer includes at least one selected from the group consisting of silicon oxide, silicon oxynitride, silicon nitride, silicon boronitride, silicon borocarbide, and silicon boro-carbonitride. In one or more of the foregoing and following embodiments, the middle layer includes polysiloxanes containing at least one metal element constituting the absorber layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a reflective mask, the method comprising:
forming an adhesion layer over a mask blank, the mask blank including a substrate, a reflective multilayer disposed over the substrate, a capping layer disposed over the reflective multilayer, an absorber layer disposed over the capping layer, and a hard mask layer disposed over the absorber layer;
forming a photoresist pattern over the adhesion layer;
patterning the adhesion layer containing carbon;
patterning the hard mask layer; and
patterning the absorber layer using the patterned hard mask layer as an etching mask, wherein the photoresist layer has a higher adhesiveness to the adhesion layer than to the hard mask layer.

2. The method of claim 1, wherein the adhesion layer includes a carbon-rich layer having a higher carbon concentration than at least one of the photoresist layer or the hard mask layer.

3. The method of claim 1, wherein a thickness of the adhesion layer is in a range from 2 nm to 50 nm.

4. The method of claim 1, wherein the adhesion layer includes an organic polymer.

5. The method of claim 1, wherein the adhesion layer includes more than 90 atomic % carbon.

6. The method of claim 5, wherein the adhesion layer includes one or more layers of graphene.

7. The method of claim 5, wherein the adhesion layer includes an amorphous carbon.

8. A method of manufacturing a reflective mask, the method comprising:
forming an adhesion layer over a mask blank, the mask blank including a substrate, a reflective multilayer disposed over the substrate, a capping layer disposed over the reflective multilayer, an absorber layer disposed over the capping layer, and a hard mask layer disposed over the absorber layer;
forming a photoresist pattern over the adhesion layer;
patterning the adhesion layer;
patterning the hard mask layer; and
patterning the absorber layer using the patterned hard mask layer as an etching mask,
wherein the adhesion layer is formed by coating an adhesion layer mixture over the hard mask layer, and applying heat to the coated adhesion layer mixture.

9. The method of claim 8, wherein the adhesion layer mixture includes a polymeric material, a cross-linker, a crosslinking initiator and a solvent.

10. The method of claim 9, wherein the polymeric material includes a hydrocarbon chain backbone with at least one crosslinking monomer.

11. The method of claim 10, wherein the hydrocarbon chain backbone includes one or more of a polyacrylate, a polyimide or a polyurethane.

12. The method of claim 10, wherein the crosslinking monomer includes at least one selected from the group consisting of a hydrocarbon chain that contains a hydroxyl group, an alkoxyl group having a carbon number less than 6, an amine group, a thiol group, an ester group, an alkene group, an alkyne group, an epoxy group, an aziridine group, an oxetane group, an aldehyde group, a ketone group, and a carboxylic acid group.

13. The method of claim 11, wherein the hydrocarbon chain backbone includes at least one of a homopolymer or a copolymer obtained by polymerization of at least one monomer selected from the group consisting of styrene, hydroxystyrene, hydroxyetheyl(meth)acrylate, ethyl(meth)acrylate, and (meth)acrylic acid, or a poly(hydroxystyrene-styrene-methacrylate), a poly(4-hydroxystyrene) and poly(pyromellitic dianhydride-ethylene glycol-propylene oxide).

14. The method of claim 10, wherein a weight average molecular weight of the polymeric material ranges from 100 Dalton to 20,000 Dalton.

15. The method of claim 10, wherein the crosslinking monomer includes at least one selected from the gourp consisting of a polyether polyol, a polyglycidyl ether, a vinyl ether, a glycouril, and a triazene.

16. The method of claim 10, wherein the coated adhesion layer mixture is subjected to polymerization by applying heat or ultra violet (UV) light.

17. A method of manufacturing a semiconductor device, the method comprising:
manufacturing a reflective mask by:
forming a middle layer over a mask blank, the mask blank including a substrate, a reflective multilayer disposed over the substrate, a capping layer disposed over the reflective multilayer, an absorber layer disposed over the capping layer, and a hard mask layer disposed over the absorber layer;
forming a first adhesion layer over the middle layer;
forming a photoresist pattern over the adhesion layer;
patterning the adhesion layer;
patterning the hard mask layer; and
patterning the absorber layer using the patterned hard mask layer as an etching mask;
obtaining a semiconductor wafer over which a photo resist layer is formed; and
patterning the photo resist layer by using the reflective mask

18. The method of claim 17, wherein the first adhesion layer includes a carbon-rich layer having a higher carbon concentration than at least one of the photoresist layer, the middle layer or the hard mask layer.

19. The method of claim 18, wherein the middle layer includes at least one selected from the group consisting of silicon oxide, silicon oxynitride, silicon nitride, silicon boronitride, silicon borocarbide, and silicon boro-carbonitride.

20. The method of claim 18, wherein the middle layer includes a polysiloxane containing at least one metal element constituting the absorber layer.
